(19) United States
(12) Patent Application Publication
(10) Pub. No.: US 2024/0038908 A1
(43) Pub. Date: Feb. 1, 2024

(54) PHOTO SENSOR CELL, PHOTO SENSOR AND METHOD

(71) Applicant: ams International AG, Jona (CH)

(72) Inventor: Rajesh GUPTA, Hyderabad, Telengana (IN)

(21) Appl. No.: 18/267,886

(22) PCT Filed: Dec. 8, 2021
(86) PCT No.: PCT/EP2021/084716

§ 371 Date: Jun. 16, 2023

(30) Foreign Application Priority Data
Dec. 18, 2020 (DE) 10 2020 134 178.4

(51) Int. Cl. H01L 31/0224; H01L 31/028; H01L 31/103

(52) U.S. Cl. CPC H01L 31/022408; H01L 31/028; H01L 31/103

(57) ABSTRACT

A photo sensor cell includes a semiconductor body having a well region of a first conductivity type and at least one base region of a second conductivity type different from the first conductivity type. The photo sensor cell also includes a well electrode electrically contacting the well region and a base electrode electrically contacting the base region. The photo sensor cell further includes a collection gate electrode located on top of the well region next to the base region and, seen in top view of the collection gate electrode, at least partially surrounding the base region. The collection gate electrode includes at least one gate extension running away from the base region and terminating within the semiconductor body, seen in top view of the collection gate electrode.

A photo sensor cell is provided. Moreover, a photo sensor comprising a plurality of such sensor cells and an operating method for such sensor cells are also provided.

An object to be achieved is to provide a photo sensor cell and a corresponding photo sensor and operating method, wherein the photo sensor cell has an increased sensitivity, for example, for a given amount of capacitance, compared to other types of photo sensors.

The capacitance of the sensor usually determines the amount of noise in an optimized signal amplifier used to detect and digitize such signals. Hence, a higher sensitivity for a given capacitance, alternately lower capacitance for similar sensitivity, helps to improve the signal-to-noise ratio of such sensor systems.

This object is achieved, inter alia, by a photo sensor cell, by a photo sensor and by an operating method comprising the features of the independent claims. Preferred embodiments constitute the subject-matter of the dependent claims.

In particular, the photo sensor cell described herein may be based on silicon and comprises a collector gate electrode having at least one gate extension that runs away from an associated base region. Hence, by means of the at least one gate extension, an area of a depletion state, where the region of the semiconductor under the gate is depleted of its majority carriers, can be increased. This depletion region in a semiconductor is also called a space charge region, SCR region for short, since the absence of the majority carriers uncovers the charged immobile dopants. Thus, a photo sensor cell that is more sensitive and that has a lower capacitance than known photo diodes, like the island photodiode or n-well photodiode, can be achieved.

The photo sensor cell described herein could enable creation of high sensitivity and low noise sensors that can be applied to several applications like ambient light sensors, ALS for short, proximity sensors, or flicker detection, especially for behind-OLED applications. These would be suitable for difficult environments like behind displays where the signal is diminished, or in applications in which high sensitivity and/or fast response is required.

With the photo sensor cell described herein, a significantly improved sensitivity-to-capacitance ratio can be achieved, providing a high sensitivity and low capacitance per light collection area.

Further, this photo sensor cell can be enabled in standard CMOS process and otherwise does not necessarily require special or additional manufacturing processes. This translates to a significant cost reduction for the manufacture of the corresponding chip.

According to at least one embodiment, the photo sensor cell includes a semiconductor body. For example, the semiconductor body is of Si. However, the semiconductor body could also comprise or could consist of other semiconductor materials like Ge, or of compound semiconductor materials like AlInGaAs or AlInGaP. It is possible that the semiconductor body comprises a substrate and a semiconductor layer sequence on the substrate, for example, epitaxially grown onto at least one side of the semiconductor body. The substrate and the semiconductor layer sequence may be of the same semiconductor material or of different semiconductor materials. In the following, for simplicity, only the semiconductor body as a whole is regarded.

According to at least one embodiment, the semiconductor body comprises a well region of a first conductivity type and a base region of a second conductivity type different from the first conductivity type. For example, the well region is p-doped and the base region is n-doped. It is possible that the base region is embedded in the well region. Although there can be a plurality of base regions and/or of well regions, for simplicity, in the following the photo sensor cell is described to include one base region and one well region. However, all features can analogously applied to the case of a plurality of base regions and/or of a plurality of well regions.

According to at least one embodiment, the photo sensor cell includes a well electrode electrically contacting the well region. The well electrode may be in direct contact with the well region or there can be at least one intermediate layer, like a highly doped well contact region, included in the semiconductor body. For example, the well electrode is of a metal like Ag, Al, Cu or W, or includes at least one such metal, or the well electrode is of a semiconductor material like poly-Si. Further, there may other metals or materials like titanium or titanium nitride to enable a good Ohmic contact between the well electrode metal and the well semiconductor material.

According to at least one embodiment, the photo sensor cell includes a base electrode electrically contacting the base region. Preferably, the base electrode is in direct contact with the base region, or there can be at least one intermediate layer, like a highly doped base contact region. For example, similar to the well electrode, the base electrode may be of a metal like Ag, Al, Cu or W, or includes at least one such metal, or the base electrode can also be of a semiconductor material like poly-Si. Further, there may be other metals or materials like titanium or titanium nitride to enable a good Ohmic contact between the base electrode metal and the base semiconductor material.

According to at least one embodiment, the photo sensor cell includes a collection gate electrode. The collection gate electrode may be located on top of the well region next to the base region, with at least one edge overlapping or close to the base region and at least one edge overlapping the well region. Seen in top view of the collection gate electrode, the collection gate electrode partially or completely surrounds the associated base region. If there is a plurality of base regions and/or of well regions, then there can be one common collection gate electrode, or there can be a grouping of several base regions to only one collection gate electrode, or there can also be a one-to-one assignment between base regions and collection gate electrode.

According to at least one embodiment, the collection gate electrode comprises one or a plurality of gate extensions. The at least one gate extension runs away from the base region, seen in top view of the collection gate electrode. That is, the at least one gate extension can be a finger-like or fork-like structure having a region of maximum extent that can be arranged radially relative to the assigned base region.

It is possible that the collection gate electrode comprises a central part directly at the associated base region, seen in top view, and that at least one gate extension starts as an edge of the base region. Hence, the optional central part of the collection gate may run around the respective base region and the at least one gate extension may run away from the associated base region partially or completely in a radial manner.

In at least one embodiment, the photo sensor cell comprises a semiconductor body having a well region of a first conductivity type and at least one base region of a second conductivity type different from the first conductivity type. Further, the photo sensor cell comprises a well electrode electrically contacting the well region and a base electrode electrically contacting the at least one base region, and a collection gate electrode located on top of the well region next to the at least one base region and, seen in top view of the collection gate electrode, at least partially surrounding the at least one base region. The collection gate electrode comprises at least one gate extension running away from the at least one base region, seen in top view of the collection gate electrode.

By means of the at least one gate extension, in a collection state, where the collection gate electrode is biased to create a depletion under the gate, of the collection gate electrode a depletion region can be extended so that the area of effective collection of photo generated carriers is extended, in particular towards the at least one well region.

This extension of the collection region per base allows us reduce the number of base regions for a given collection area and hence reduces the photodiode capacitance.

There are many ways to shape the collection gate extensions, and in the following only a few examples are described. For example, a total length of the gate extensions from the base region can limit the speed of collection since the carriers need to diffuse through all this length. This may or may not be a concern depending on the detection speed required in the specific application of the sensor cell.

Another key parameter is the sensor cell capacitance, not counting the collection gate electrode, since the latter is a separate terminal. The sensor cell capacitance is a function of number of base regions, size of each base region, hence, capacitance per base region, and routing or wiring capacitance which can be significant.

Hence, for example, by setting the location and the number of the at least one base region and by varying the total length of the gate extensions, which depends on the location of the at least one base region, emphasis can be given more to detection speed or more to capacitance reduction.

According to at least one embodiment, when the collection gate electrode is in an off-state, and there is an accumulation region under the gate electrode near the interface of the semiconductor and dielectric region. In this state, the depletion region, also referred to as SCR, at the interface between the well region and the at least one base region, does not extend under the gate electrode in the direction away from this interface. It is possible that in the off-state the base to well depletion region and the collection gate electrode does not overlap in the direction away from the base-well interface at all, seen in top view of the collection gate electrode. For example, in the off-state, at most 20% or at most 40% of a base area of the collection gate electrode are undercut by the depletion region.

According to at least one embodiment, when the collection gate electrode is in a collection-state, the depletion region is extended below the collection gate electrode and/or completely burrows under the collection gate electrode. For example, in this state the semiconductor interface under the gate electrode is depleted but may not be inverted. Hence, in the collection-state at least 80% or at least 95% or even 100% of the area of the collection gate electrode may be undercut by the depletion region.

Based on the collection gate voltage, the semiconductor material under the gate electrode may be
a) in an accumulation state, so that there are excess majority carriers near the interface, corresponding to an off-state of the collection gate electrode, or
b) in a depletion state, corresponding to a collection-state, in which the semiconductor region under the collection gate electrode is depleted and is free of carriers of both the majority and minority type, or
c) in an inversion state, whereas there can be weak or strong inversion, where the semiconductor interface under the collection gate electrode has more minority carriers than majority carriers. This state may be avoided to be biased, because this state may be a no-state in a MOSFET.

According to at least one embodiment, an area content of the collection gate electrode, or of a collection area caused by the collection gate electrode, exceeds an area content of the base region by at least a factor of three or by at least a factor of five or by at least a factor of 15, seen in top view of the collection gate electrode. In other words, seen in top view, the collection gate electrode or the collection area is considerably larger than the assigned base region. For example, said factor is at most 10³ or at most 100 or at most 60. Hence, the depletion region can significantly be extended.

It is not necessarily the collection gate area but the collection area which is significantly increased compared with the base region, seen in top view. In an extreme case, there may be a narrow but long collection gate electrode, with a small gate area, but the collection area, which is approximately 40 μm times a gate extension length, could be much larger.

According to at least one embodiment, a maximum dimension of the collection gate electrode exceeds a maximum dimension of the base region, seen in top view. For example, a maximum length of the collection gate electrode exceeds a diameter of the base region by at least a factor of five or by at least a factor of 15 and/or by at most 10³ or at most 100 or at most 60. The length of the collection gate electrode may be a length of the respective gate extensions along a center axis of the respective gate extensions, and for the diameter d of the base region it may apply, depending on an area A of the base region, seen in top view: d=2(A/π)^{0.5}.

According to at least one embodiment, the collection gate electrode and the base region overlap to at most 40% or to at most 20% or to at most 10% of an average width of the at least one gate extension and/or of an average width of the optional central part of the collection gate electrode, seen in top view of the collection gate electrode. In other words, the collection gate electrode is predominantly or almost completely or completely located next to the assigned base region in a non-overlapping manner. Hence, the collection gate electrode and the respective base region may not or not significantly overlap, seen in top view, so that the base region can efficiently be electrically addressed and is not strongly influenced by the collection gate electrode.

According to at least one embodiment, seen in top view, a maximum distance between any point of the top side and the nearest collection gate electrode is at most 40 μm or is at most 30 μm or is at most 20 μm. By having such a maximum distance, it can be assured that nearly all photo-generated carrier can reach a depletion region through diffusion before getting recombined. An average length a photo-generated minority carrier diffuses before recombining is called diffusion length. For effective collection, all points on the photodiode should be within a few diffusion lengths to the depletion region, in this case the collection gate electrode, for example, within two or three or four diffusion lengths. Preferably, the following specific design examples all take into account this design rule.

According to at least one embodiment, the collection gate electrode comprises at least two and at most eight of the gate extensions. For example, the collection gate electrode comprises exactly 2 or 4 or 8 of the gate extensions.

If there is a plurality of the gate extensions, all the gate extensions can have the same shape and size, or can have at least the same shape but different sizes, or are of different size and of different shape.

According to at least one embodiment, the at least one gate extension, or at least one of the gate extensions, comprises a furcation. There can be just one or a plurality of furcations per gate extension. The furcation can be a bifurcation or a trifurcation or otherwise a multi-furcation.

According to at least one embodiment, the at least one gate extension, or at least one of the gate extensions, is of T-shape, seen in top view of the collection gate electrode. Hence, a width of said collection gate electrode can be largest at an end of the respective gate extension remote from the assigned base region. Accordingly, the respective gate extension may comprise exactly one bifurcation, and the two resulting branches can run obliquely, in particular perpendicularly, with a trunk from which the branches furcate.

According to at least one embodiment, the at least one gate extension, or at least one of the gate extensions, is of L-shape. Hence, said collection gate electrode may comprise exactly one kink and/or bend, seen in top view of the collection gate electrode. Said collection gate electrode may be free of any furcation. The term ‘L-shape’ can refer to kink and/or bend of 90°, but other bending angles or kinking angles are also possible, for example, angles of at least 20° or of at least 45° and/or of at most 160° or of at most 135°.

A kink may refer to a sharp change of direction, whereas a bending may refer to a change of direction with a significant radius of curvature so that a local rounding could result.

According to at least one embodiment, the at least one gate extension, or at least one of the gate extensions, is of meander shape. Hence, said collection gate electrode comprises a plurality of changes in direction, seen in top view of the collection gate electrode. For example, the number of changes in direction is at least two or at least four and/or said number of changes in direction is at most 20 or is at most ten or is at most five. All the changes in direction can be bends or kinks, and all the changes in direction can be of the same angle or of different angles.

According to at least one embodiment, the at least one gate extension, or at least one of the gate extensions, has the shape of a straight line section, seen in top view of the collection gate electrode. Hence, said gate extensions may be free of any changes in direction and of any furcation.

According to at least one embodiment, the at least one gate extension, or at least one of the gate extensions, has the shape of an F or of a double-F when seen in top view of the collection gate electrode.

According to at least one embodiment, the at least one gate extension, or at least one of the gate extensions, has the shape of comb or of a double comb when seen in top view of the collection gate electrode. If there is a plurality of combs, these combs can be arranged in an indented manner.

According to at least one embodiment, differently shaped gate extensions are combined with one another. Hence, not all of the gate electrodes need to have the same shape, seen in top view.

According to at least one embodiment, there is a plurality of base regions. Each one of the base regions can be provided with its own collection gate electrode having gate extensions. It is possible that all the base regions have collection gate electrodes of the same shape, but differently shaped collection gate electrodes can also be applied. Moreover, the collection gate electrodes of different base regions may be rotated relative to one another, for example, by 90°.

According to at least one embodiment, the base regions are electrically connected. Thus, the sensor cell may comprise at least one base connection line running between the base regions. It is possible that the at least one base connection line and the at least one gate extension overlap partially, seen in top view of the top side.

According to at least one embodiment, the photo sensor cell further comprises ore or a plurality of transfer gate electrodes. For example, the at least one transfer gate electrode is located between the base region and the collection gate electrode, seen in top view of the collection gate electrode. The term ‘between’ means, for example, that there is no straight connection line between the collection gate electrode and the assigned base region not running through the transfer gate electrode. By means of the transfer gate electrode, reading out the sensor cell can precisely be controlled.

In the following, only designs with one transfer gate electrode are explicitly mentioned, however, there can be a plurality of transfer gate electrodes. If there is a plurality of transfer gate electrodes and/or of base regions, then there can be a one-to-one assignment between transfer gate electrodes and collection gate electrodes and/or base regions, or a couple of transfer gate electrodes are assigned to one common collection gate electrode.

According to at least one embodiment, the transfer gate electrode is electrically independently addressable from the at least one assigned collection gate electrode. Hence, a bias voltage can be applied to the transfer gate electrode and the assigned collection gate electrode is applied with a different bias voltage, or vice versa. Of course, both the transfer gate electrode and the assigned collection gate electrode can be addressed to be at the same electric potential.

According to at least one embodiment, the transfer gate electrode is configured to form a transfer depletion region from below the collection gate electrode to the assigned base region when in an on-state. Accordingly, forming the transfer depletion region by addressing the transfer gate electrode may result in a continuous depletion region from below the collection gate electrode to the base region which is otherwise not present, when the transfer gate is off. The length of the transfer gate electrode may be sufficiently long to ensure that when the transfer gate is off, the depletion region under the collection gate electrode is isolated from the depletion region at the interface of the base and well regions.

Hence, by means of the transfer gate electrode a time interval can be defined in which charge carriers can be transferred from the depletion region, in particular from the extended depletion region under the collection gate electrode, to the base region. If the transfer gate electrode is in an off-state, such a charge carrier transfer may essentially or completely be suppressed.

According to at least one embodiment, the transfer depletion region completely surrounds the base region, seen in top view of the collection gate electrode. This transfer gate isolates the base region from the depletion region under the collection gate. Hence, without the transfer depletion region created by addressing the transfer gate electrode, the assigned base region cannot collect charge carriers.

According to at least one embodiment, the transfer gate electrode and the collection gate electrode are completely or predominantly disjunctive, seen in top view of the collection gate electrode. However, the transfer gate electrode and the collection gate electrode are placed close to one another, such that when the transfer gate electrode is turned-on, the depletion region from the transfer gate electrode and the depletion region from the collection gate electrode overlap.

According to at least one embodiment, the collection gate electrode comprises one or more than one axis of mirror symmetry, seen in top view of the collection gate electrode. For example, there is one axis of mirror symmetry or there are two or four axes of mirror symmetry.

According to at least one embodiment, the collection gate electrode surrounds the base region over at least one angle range of a minimum angle of at least 300° or of at least 330° or of at least 350°, seen in top view of the collection gate electrode. Said angle range can be a continuous angle range or said angle range is composed of a couple of sub-ranges that collectively amount to the stated minimum angle. Said angle range may be determined seen from a center of area of the assigned base region, seen in top view.

According to at least one embodiment, the transfer gate electrode does not surround the base region and extends away from it. For example, there is a small region where the transfer gate electrode is close to or overlaps the base region.

According to at least one embodiment, the collection gate electrode does not surround the transfer gate region and extends away from it. For example, there is a small region where the collection gate electrode is close to the transfer gate electrode.

According to at least one embodiment, the photo sensor cell comprises exactly one well region, exactly one base region, exactly one base electrode and exactly one collection gate electrode. Otherwise, there can be more than one of the stated regions.

According to at least one embodiment, the base region is surrounded all around by the well region, seen in top view of the collection gate electrode. Otherwise, the base region can be located at an edge of the well region.

According to at least one embodiment, the base region is n⁺-doped and the well region is p-doped.

For example, a doping concentration of the base region is at least 1×10¹⁹ cm⁻³ or at least 5×10¹⁹ cm⁻³ or at least 2×10²⁰ cm⁻³. Alternatively or additionally, said doping concentration is at most 10²² cm⁻³ or at most 2×10²¹ cm⁻³ or at most 1×10²¹ cm⁻³.

For example, a doping concentration of the well region is at least 1×10¹⁴ cm⁻³ or at least 1×10¹⁷ cm⁻³ or at least 2×10¹⁸ cm⁻³. Alternatively or additionally, said doping concentration is at most 1×10²⁰ cm⁻³ or at most 1×10¹⁹ cm⁻³ or at most 6×10¹⁸ cm⁻³.

According to at least one embodiment, the semiconductor body further comprises one or a plurality of well contact regions. The well contact region is electrically between the well electrode and is configured to improve electric contact between the well electrode and the well region. For example, the at least one well contact region is p⁺-doped. Concerning the doping concentration of the well contact region, the same applies as for the base region.

According to at least one embodiment, the gate extension or some of the gate extensions or all of the gate extensions terminate(s) within the semiconductor body, seen in top view of the collection gate electrode. In other words, the respective gate extension does not reach an edge of the semiconductor body. In particular, there is no electric connection applied onto the respective gate extension and reaching to an exterior of the photo sensor cell. For example, a minimum distance between the respective gate extension and the edge of the semiconductor body is at least 10 μm or at least 20 μm and/or at most 0.1 mm or at most 60 μm, seen in top view of the semiconductor body and/or seen in top view of the collection gate electrode.

As an option, there can be at least one additional electrode in addition to the at least one gate extensions, wherein, seen in top view of the semiconductor body and/or seen in top view of the collection gate electrode, the additional electrode reaches the edge of the semiconductor body and may run beyond the edge of the semiconductor body, that is, outside the semiconductor body.

A photo sensor is additionally provided. The photo sensor comprises at least one photo sensor cell as indicated in connection with at least one of the above-stated embodiments. Features of the photo sensor cell are therefore also disclosed for the photo sensor and vice versa.

In at least one embodiment, the photo sensor comprises a plurality of the photo sensor cells. Preferably, the photo sensor cells are arranged adjacent to one another, seen in top view of the collection gate electrodes. In other word, seen in top view, the photo sensor cells do not overlap each other.

A method for operating the photo sensor or the photo sensor cell is additionally provided. By means of the method, a photo sensor and/or a photo sensor cell is operated as indicated in connection with at least one of the above-stated embodiments. Features of the photo sensor and of the photo sensor cell are therefore also disclosed for the method and vice versa.

In at least one embodiment, the method is for operating a photo sensor cell and comprises:
illuminating the photo sensor cell with electromagnetic radiation so that electron-hole pairs are generated in the semiconductor body, and
providing a gate voltage to the collection gate electrode, so that a collection region for charge carriers in the semiconductor body towards the base region is increased compared with an off-state of the collection gate electrode.

A photo sensor cell, a photo sensor and a method described herein are explained in greater detail below by way of exemplary embodiments with reference to the drawings. Elements which are the same in the individual figures are indicated with the same reference numerals. The relationships between the elements are not shown to scale, however, but rather individual elements may be shown exaggeratedly large to assist in understanding.

In the Figures:

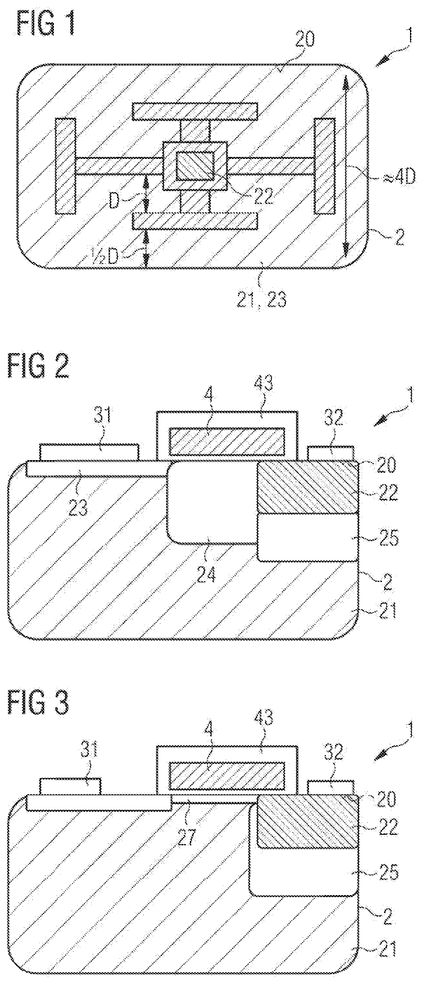

FIG. 1 shows a schematic top view of an exemplary embodiment of a photo sensor cell described herein,

FIGS. 2 and 3 show schematic sectional views of the photo sensor cell of FIG. 1 in different collection gate states,

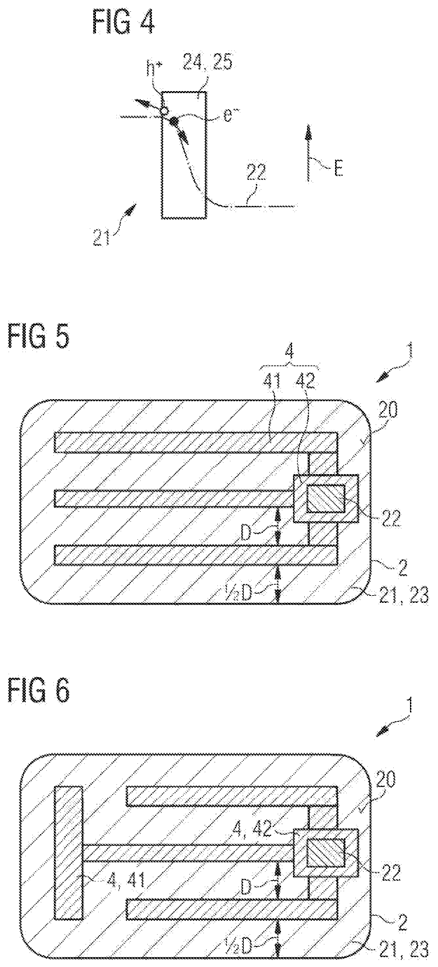

FIG. 4 shows a schematic representation of an energy band diagram of the depletion region of the photo sensor cell of FIG. 2,

FIGS. 5 to 7 show schematic top views of exemplary embodiments of photo sensor cells described herein,

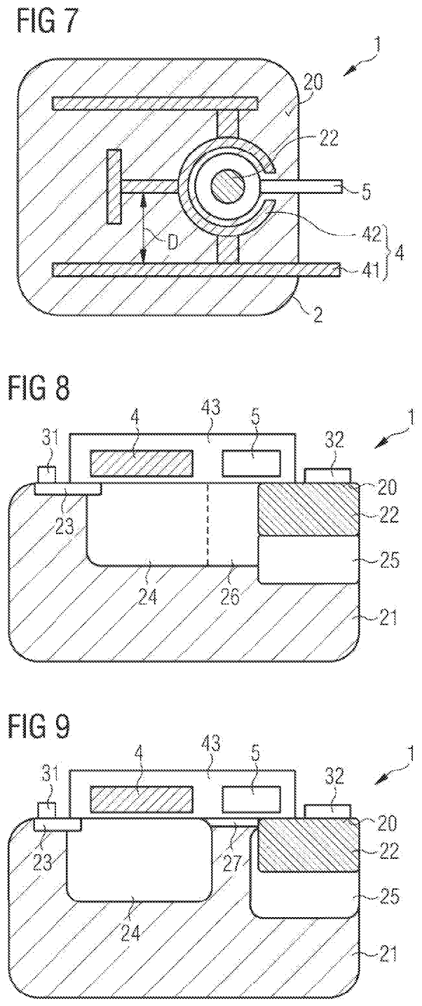

FIGS. 8 and 9 show schematic sectional views of the photo sensor cell of FIG. 7 in different transfer gate states,

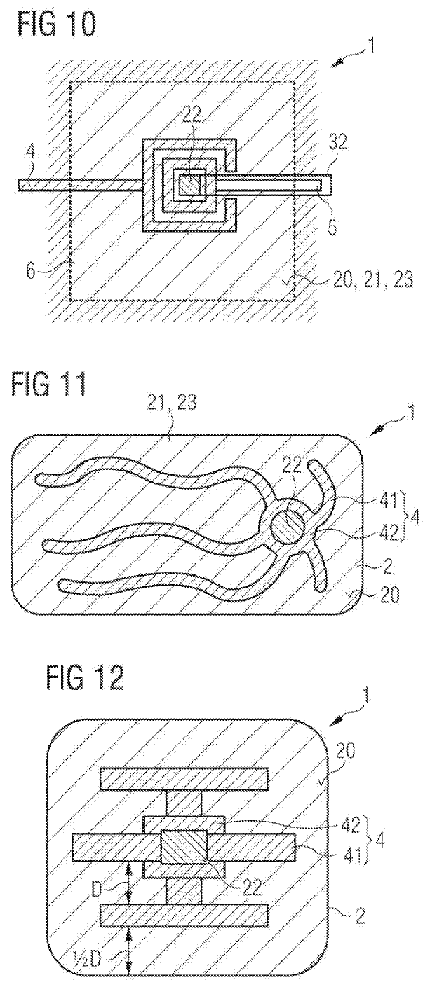

FIGS. 10 and 11 show schematic top views of exemplary embodiments of photo sensor cells described herein,

FIGS. 12 to 18 show schematic top views of exemplary embodiments of photo sensor cells described herein,

FIG. 19 shows a schematic top view of an exemplary embodiment of a photo sensor described herein,

FIG. 20 shows a schematic sectional view of a modified photo sensor cell,

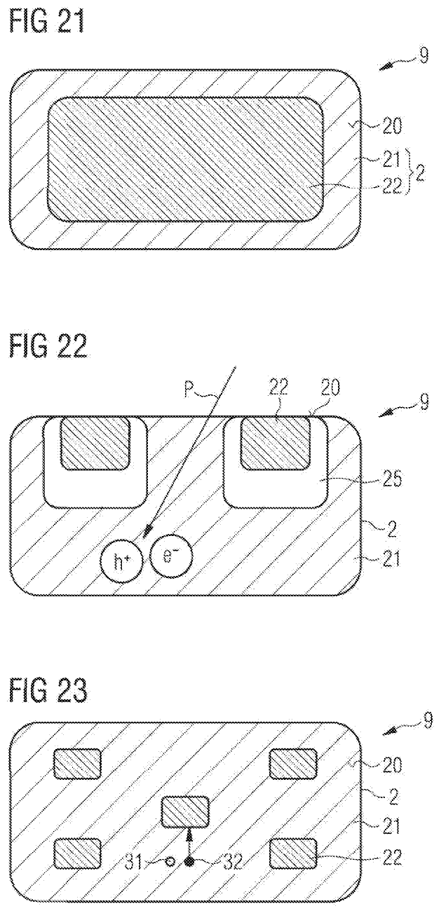

FIG. 21 shows a schematic top view of the modified photo sensor cell of FIG. 20,

FIG. 22 shows a schematic sectional view of a modified photo sensor cell,

FIG. 23 shows a schematic top view of the modified photo sensor cell of FIG. 22,

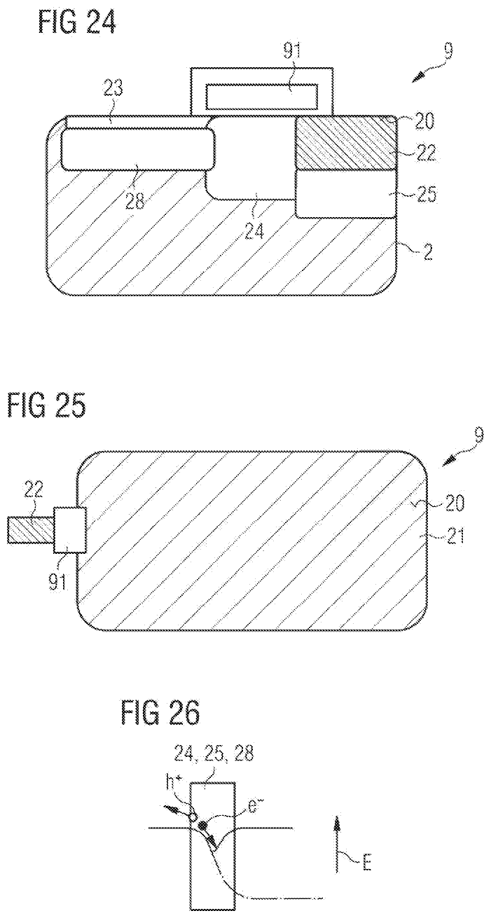

FIG. 24 shows a schematic sectional view of a modified photo sensor cell,

FIG. 25 shows a schematic top view of the modified photo sensor cell of FIG. 24, and

FIG. 26 shows a schematic representation of an energy band diagram of the modified photo sensor cell of FIG. 24.

In FIGS. 1 to 4, a method for operating a photo sensor cell 1 is illustrated. The photo sensor cell 1 comprises a semiconductor body 2. Preferably, the semiconductor body 2 is of silicon, but other semiconductor materials are also possible. Most of the semiconductor body 2 is formed by a well region 21. For example, the well region 21 is p-doped and can thus be regarded as a p-well. A doping concentration of the well region 21 is, for example, around 1×10¹⁴ cm⁻³.

In the semiconductor body 2, there is also a base region 22 which is embedded in the well region 21. The base region 22 is, for example, n-doped and may be referred to as n-well. Part of a top side 20 of the semiconductor body 2 is formed by the base region 22. A doping concentration of the base region 22 is, for example, around 5×10²⁰ cm⁻³.

Further, the photo sensor cell 1 includes a collection gate electrode 4 arranged on the top side 20. The collection gate electrode 4 does not significantly overlap with the base region 22, seen in top view of the top side 20. The collection gate electrode 4 is electrically insulated from the semiconductor body 2 by means of a collection gate insulator 43, for example, silicon dioxide. Moreover, there is a well electrode 31 and a base electrode 32 to electrically contact the well region 21 and the base region 22, respectively. Other than shown, there can be more than one well electrode 31. As an option, the semiconductor body 2 includes a base contact region 23 which is of the same conductivity type as the well region 21 and, thus, may be p-doped. A doping concentration of the base contact region 23 is, for example, around 5×10²⁰ cm⁻³.

When negative voltage is applied on the collection gate electrode 4, at an interface between the well region 21 and the base region 22 a depletion region 25 occurs due to diffusion of majority chare carriers, see FIG. 3. Said depletion region 25 is essentially limited to said interface. Upon application of an even more negative voltage to the collection gate electrode 4, there may be an accumulation region 27.

In the case of doping types as stated above, when a small negative voltage is applied to the collection gate electrode 4, see FIG. 2, an extended depletion region 24 results. The extended depletion region 24 preferably completely or nearly completely extends beyond the collection gate electrode 4 and adjoins the intrinsically formed depletion region 25 and, hence, significantly enlarges the overall depletion region 24, 25.

Upon absorption of a photon, not shown in FIGS. 1 to 4, in the semiconductor body 2, a pair of charge carriers, that is, an electron e⁻ and a hole h⁺, are generated. As illustrated in the energy E diagram in FIG. 4, in the depletion region 24, 25 the charge carriers e⁻, h⁺ separate and a photo voltage results. Put in simple words, in the depletion region 24, 25 electrons e⁻ fall like rocks, and holes h⁺ float up like bubbles in the potential in the depletion region 24, 25. When only a flat potential created, the charge carriers e⁻, h⁺ just move randomly until they recombine or one falls off the slope. The depletion region 24, 25 may also be referred to as a space charge region, SCR for short.

With the collection gate electrode 4 on, see FIG. 2, depletion is sufficient. The gate voltage may be optimized to reduce leakage. The SCR under the collection gate electrode 4 collects the photo-generated electrons e⁻ and transports them to the base electrode 22 which may be a cathode.

Hence, by increasing the depletion region 24, 25, detection efficiency of photo-generated charge carriers can be increased.

For this reason, see in particular FIG. 1, the collection gate electrode 4 comprises gate extensions 41. The gate extensions 41 may start to run away from the assigned base region 22 from an optional center region 42 directly at the base region 22.

As illustrated in FIG. 1, for example, the gate extensions 41 may be of T-shape when seen in top view of the top side Hence, each one of the gate extensions 41 comprises a trunk running radially away from the base region 22. At ends of the trunks, there are bifurcations so that branches run away from the respective trunk in a perpendicular manner. Hence, there are two axes of symmetry, seen in top view.

Seen in top view of the top side 20, the photo sensor cell 1 is of roughly rectangular shape, wherein corners may be rounded. Accordingly, the gate extensions 41 running towards the short sides of said rectangle have longer trunks and shorter branches than the gate extensions 41 running towards the longer sides of said rectangle.

For example, a length of the shorter sides of said rectangle is four times or about four times a scale parameter D. Hence, in particular seen in parallel with the shorter sides, a distance of the branches towards the edges of the top side 20 and a distance between the branches and the trunks running in parallel with each other amounts about to the scale parameter D and 0.5 D, respectively, for example, to at least 0.7 D and/or to at most 1.3 D and to at least 0.3 D and/or to at most 0.8 D, respectively. For example, D is at least 2 μm or at least 0.01 mm and/or at most 0.1 mm or at most 0.04 mm.

As an option, a width of the trunks and of the branches may be at least 0.02 D or at least 0.05 D and/or at most 0.2 D or at most 0.1 D; the same can apply for a width of the central part 41. For example, a width of the gate extensions 41 is at least 1 μm and/or at most 5 μm. Said width may also be referred to as line width

By having such a scale parameter D, it can be assured that each point of the top side 20 is at most 2 D away from the nearest gate extension 41. Preferably, this distance is at most 40 μm or at most 20 μm.

Although in parallel with the longer side of the rectangle constituting the top side 20, a distance of the branches towards the edges of the top side 20 is D. A distance between ends of the branches of adjacent gate extensions 41 is, for example, at least 0.5 D or at least 1.2 D and/or at most 3 D or at most 2 D. An aspect ratio, that is, a ratio of the long edges to the short edges, of the rectangle that constitutes the top side 20 may be at least 1.2 and/or at most 2.5.

For example, a depth of the base region 22 is at least 50 nm and/or at most 0.3 μm. Additionally or alternatively, a depth of the optional base contact region 23 is at least 30 nm and/or at most 0.2 mm. Additionally or alternatively, a thickness of the well region 21 is at least 0.5 μm or at least 2 μm. If the semiconductor body 2 includes a substrate, a thickness of the well region 21 and therefore of the semiconductor body may be up to 2 mm or up to 0.5 mm.

Although the top side 20 is a rectangle in FIG. 1, other shapes of the top side 20 like squares or hexagons are also possible.

Hence, a unit cell 1 comprising primarily an n-diffusion zone 22 surrounded by the gate 4 with the gate 4 extending in different directions is made possible, and many such unit cells 1 placed in a uniform grid can make up a detector device 10. One way to understand the device 1, 10 is to think of the depletion region 24, 25 under the collection gate electrode 4 as ‘magnets’ to attract and collect charges from photo generation in neighboring regions. The collection gate electrodes 4 extend the reach of the n-diffusion, however, if the collection gate electrode 4 is kept in accumulation depletion mode while sensing, the n-diffusion capacitance is not affected by the network formed by the collection gate electrode 4.

Accordingly, the photo sensor cell 1 described herein uses the depletion region 24 generated by the collection gate electrode 4 to effectively increase the range of the charge collection and to get all the charge into a small diffusion region, that is particularly the base region 22. This gives a high voltage per unit area collecting the photo charge.

This device 1, 10 may be used for applications involving sensing of light. This device 1, 10 can especially be useful, if cost is important and/or high performance is required.

In FIG. 5, another exemplarily embodiment of the photo sensor cell 1 is illustrated. In this case, the base region 22 and, thus, the base electrode, not shown, are placed near an edge of the top side 20 in order to reduce cathode wiring capacitance and in order to increase signal strength. Cathode wiring capacitance may be a significant fraction of overall cathode capacitance so that by means of placing the base region 22 near the edges, overall cathode capacitance can be reduced significantly.

There is one central gate extension 41 which runs along a straight line away from the optional central part 42. Moreover, there are two L-shaped gate extensions 41. It is possible that all the gate extensions 41 terminate flush with each other on the edge of the top side 20 remote from the base region 22. A distance between adjacent gate extensions 41 is, for example, at least 0.7 D and/or at most 1.3 D, at least in the region where all the gate extensions 41 run in parallel with each other. Hence, there is only one axis of symmetry, seen in top view.

The design as shown in FIG. 5 enables a reduction in wiring capacitance, by bringing the base electrode close to the edge of the sensor cell 1. Now this base electrode can be connected to a circuit placed beside the sensor cell 1 with a short wire that minimizes capacitance.

Otherwise, the same as to FIGS. 1 to 4 may also apply for FIG. 5.

In FIG. 6, another exemplarily embodiment of the photo sensor cell 1 is illustrated. In this case, there are two gate extensions 41 of L-shape and one middle gate extension 41 of T-shape. Long legs of the L-shaped gate extensions 41 run in parallel with the long sides of the rectangle that forms the top side 20, said rectangle may have rounded corners. An angle between the respective long and short legs of the L's may be 90° or about 90°. A distance between the branches of the middle gate extension 41 to the L-shaped gate extensions 41 is, for example, at least 0.5 D and/or at most 2 D or at most 1.5 D. For example, a distance between the nearby edge of the top side 20 and the base region 22 is at least 0.5 D and/or at most 2 D or at most 1.5 D.

Otherwise, the same as to FIG. 5 may also apply for FIG. 6, and vice versa.

In FIGS. 7 to 9, another exemplarily embodiment of the photo sensor cell 1 is shown. In this case, the photo sensor cell 1 further comprises a transfer gate electrode 5. The transfer gate electrode 5 may or may not completely surround the base region 22. From the circular region of the transfer gate electrode 5 next to the base region 22, an extension may run to an exterior of the top side 20 in order to electrically contact the transfer gate electrode 5.

The transfer gate electrode 5 is arranged on the top side 20 next to the base region 22 and may slightly overlap with the base region 22. For example, at most 20% of the base region 22 are covered by the transfer gate electrode 5. Further, the transfer gate electrode 5 is located between the base region 22 and the collection gate electrode 4.

The collection gate electrode 4 nearly completely surrounds the base region 22 and, thus, the transfer gate electrode 5, except the extension of the transfer gate electrode 5 that is to electrically contact the transfer gate electrode 5. Therefore, the collection gate electrode 4 comprises the optional central part 42 which is of circular shape extending around the base region 22 along an angular range of at least 330°, for example. The central part 42 is distant from the transfer gate electrode 5. The collection gate electrode 4 and the transfer gate electrode 5 can be embedded in the same gate insulator 43.

For example, the collection gate electrode 4 comprises three of the gate extensions 41, which are all of T-shape. The two gate extensions 41 at the edges of the top side 20 comprise a short trunk and long branches, whereas the middle gate extension 41 comprises a relatively long trunk and braches shorter than the trunk of said gate extension 41.

The middle gate extension 41 may be shorter than the outward gate extensions 41. Hence, a distance of the middle gate extension 41 to the edges of the top side 20 may be at least 1.5 D and/or at most 3 D. Other than shown, all the gate extensions 41 may terminate flush with each other at the edge of the top side 20 remote from the base region 22.

As in all other exemplary embodiments, the base region 22 does not need to be of square shape, seen in top view, but can also be of round shape.

As an option, one of the gate extensions 41 at the edges of the top side 20 can comprise a further extension to electrically contact the collection gate electrode 4.

Disregarding said further extension, seen on the top side 20 there is one axis of symmetry concerning the design of the gate electrodes 4, 5.

By means of the transfer gate electrode 5, see FIGS. 8 and 9, a transfer depletion region 26 can be generated. If the transfer depletion region 26 is generated when the transfer gate electrode 5 is in an on-state, then the extended depletion region 24 resulting from the collection gate electrode 4 and the intrinsic depletion region 25 at the interface between the base region 22 and the well region 21 join. Hence, carrier can be transferred from the collection gate electrode 4 to the base region 22 only when the transfer gate electrode 5 is applied with a voltage.

Hence, if the collection gate electrode 4 is always on and there is a DC bias, then the extended depletion region 24 is generated. The collection gate electrode 4 then acts as an electron trap. All electrons trapped here may only be released to the cathode at the base region 22. With the transfer gate electrode 5 on, the charge carriers, in particular electrons, collected under the collection gate electrode 4 are transferred to the base region 22.

With the transfer gate electrode in an off-state, the depletion region 25 and the extended depletion region 24 under the base region 22 and at the collection gate electrode 4, respectively, do not overlap. Now the collection gate electrode 4 will collect charge but not transfer to the cathode.

To reset: The transfer gate electrode is in an on-state and floating diffusion is biased to a reset voltage.

To reset for correlated double sampling, CDS for short: The transfer gate electrode 5 is in the off-state and floating diffusion is biased to the reset voltage.

To Read: Floating diffusion is ‘floating’ and the transfer gate electrode 5 is turned on.

Otherwise, the same as to FIGS. 1 to 6 may also apply for FIGS. 7 to 9.

In the embodiment of FIG. 10, the transfer gate electrode 5 and the collection gate electrode 4 are of square layout. The extensions of the gate electrodes 4, 5 to electrically contact these gate electrodes 4, 5 may run in opposite directions. The base electrode 32 and the extension of the transfer gate electrode 5 may run on top of each other or in parallel with each other.

As in all other exemplary embodiments, there can be an aperture 6 surrounded by an opaque layer like a metal layer to define a radiation collection area of the photo sensor cell 1.

Otherwise, the same as to FIGS. 7 to 9 may also apply for FIG. 10.

In the embodiment of FIG. 11, it is illustrated that the gate extensions 41 may be of curved or meander shape. Hence, at least some of the gate extensions 41 may have a couple of changes in direction. There can be one axis of symmetry, seen in top view. The same can apply to all other exemplary embodiments. Further, like in FIGS. 1, 5 and 6, also in FIG. 11 there can be a transfer gate electrode 5.

Otherwise, the same as to FIGS. 1 to 10 may also apply for FIG. 11.

According to FIG. 12, the collection gate electrode 4 comprises two different types of gate extensions 41, that is, central straight-running gate extensions 41 and two T-shaped gate extensions 41 along the edges of the top side 20.

In FIG. 13, a more complex design of the collection gate electrode 4 is illustrated. In this case, there are two T-shaped gate extensions 41 and two double-F-shaped gate extensions 41.

Otherwise, the same as to FIGS. 1 to 11 may also apply for FIGS. 12 and 13.

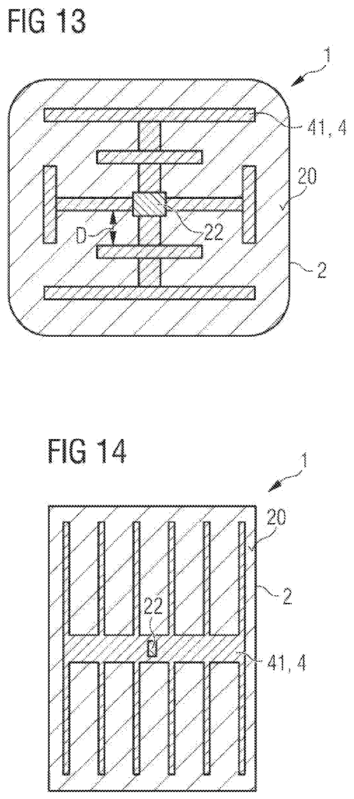

According to FIG. 14, the collection gate electrode 4 is shaped as a double-comb, so that the gate electrode 4 comprises a central bar surrounding the base region 22 and a plurality of the gate extensions 41 running away from said bar. The bar may have a larger line thickness than the gate extensions.

Otherwise, the same as to FIGS. 1 to 13 may also apply for FIG. 14.

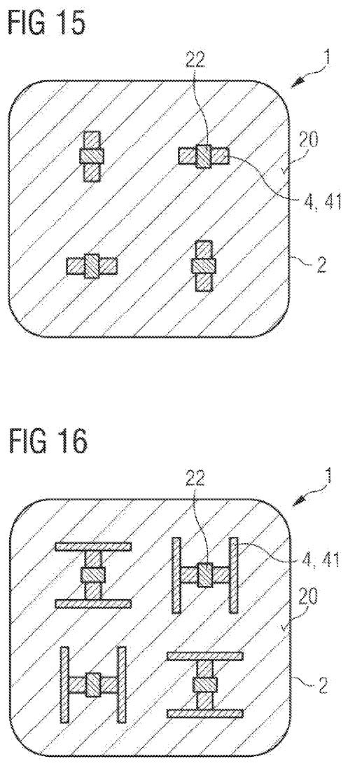

In the exemplary embodiments of FIGS. 1 to 14, there is only one base region 22. Contrary to that, the sensor cell of FIG. 15 includes a plurality of the base regions 22, for example, four base regions 22. All the base regions 22 may be provided with the same kind of collection gate electrodes 4. The collection gate electrodes 4 of the different base regions 22 may be rotated relative to one another when seen in top view of the top side 20. For example, the gate extensions 41 are all of linear design. There are two gate extensions 41 per base region 22.

Further, in FIG. 15 it is illustrated that there is no central part of the collection gate electrode 4 so that the collection gate electrode 4 does not completely surround the base region 22. Such a layout can also be present in all other exemplary embodiments.

According to FIG. 16, the individual gate extensions 41 are of T-shape. Other than shown, also L-shaped or F-shaped or double-F-shaped or meander-shaped gate extensions 41 can alternatively or additionally be used.

Otherwise, the same as to FIGS. 1 to 14 may also apply for FIGS. 15 and 16.

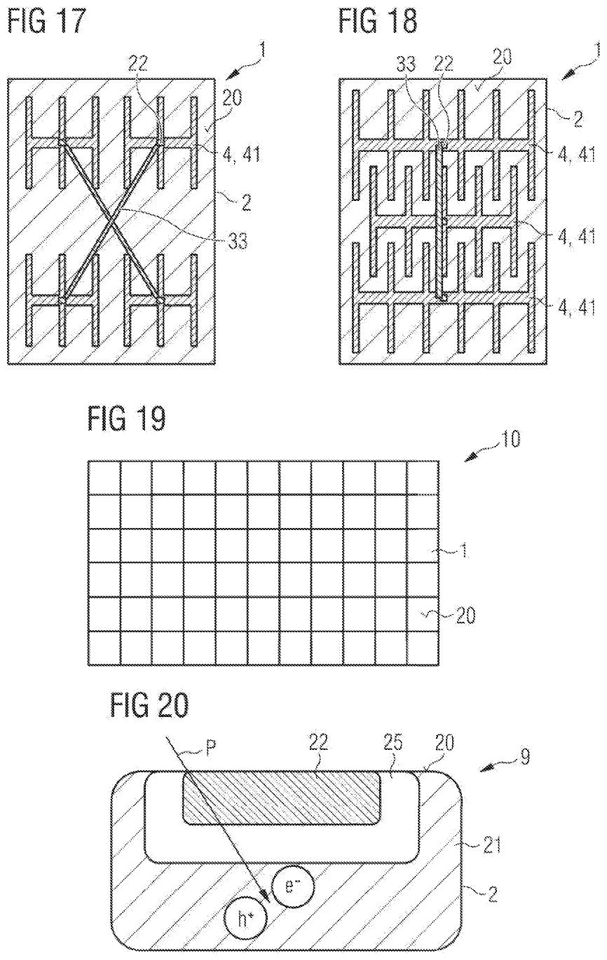

In FIG. 17 it is illustrated that the individual base regions 22 are electrically interconnected by base connection lines 33. Such base connection lines 33 can also be present in all other exemplary embodiments comprising a plurality of the base regions 22.

For example, the base connection lines 33 connect the base regions 22 in an X-shape. However, other shapes of the base connection lines 33 are also possible. For example, the base connection lines 33 may run at least in part congruent with the gate extensions 41 to minimize an area proportion of the top side 20 covered by electric lines.

In FIG. 18 it is shown that the individual collection gate electrodes 4 are of double-comb shape. As an option, a third, central collection gate electrode 4 may be arranged in an indented manner with the other two collection gate electrodes.

All the base regions 22 may be arranged on a straight line and by be connected by the linear base connection line 33.

Otherwise, the same as to FIGS. 1 to 16 may also apply for FIGS. 17 and 18.

In FIGS. 15 to 18, no transfer gate electrodes are shown, However, transfer gate electrodes could of course be present similar to FIGS. 7 to 10. There can be one common transfer gate electrode for all the base regions 22, or there is an own transfer gate electrode for each base region 22.

In FIG. 19, an exemplary embodiment of a photo sensor 1 is illustrated. The photo sensor 1 comprises a plurality of the photo sensor cells 1 as explained, for example, in connection with FIGS. 1 to 18. Preferably, the photo sensor cells 1 are arranged next to one another without overlapping each other. Between adjacent photo sensor cells 1, there can be an optical insulation, not shown.

For example, the photo sensor 10 comprises at least 100 or at least 10³ and/or at most 10⁷ or 10⁵ of the photo sensor cells 1.

In FIGS. 20 to 26, modified photo sensor cells 9 are illustrated. According to FIGS. 20 and 21, the modified photo sensor cell 9 is an n-well photo diode having one large base region 22 without any gate electrode.

In the modified photo sensor cell 9 of FIGS. 22 and 23, an island photo diode is realized comprising a couple of the base regions 22 which are separated from one another. In FIG. 22 it is briefly illustrated that a photon P is absorbed in the well region 21 so that a charge carrier pair e⁻, h⁺ results. By diffusion and by means of the depletion region 25, the charge carries e⁻, h⁺ are separated.

According to FIGS. 24 to 26, the modified photo sensor cell 9 comprises a large well region 21, and the base region 22 may be located at an edge of the well region 21, seen in top view. There can be a modified gate electrode 91 between the base region 22 and the barrier region 21. Moreover, below the base contact region 23 there can be a trap region 28. If the well region 21 is p-doped, then the trap region 28 is n-doped, and vice versa. Thus, the trap region 28 may be located between the well region 21 and the base contact region 23.

With the modified gate 91 in an off-state, charges collect in the ‘valley’—fully depleted n-doped trap region 28, until full well charge, see the solid line in FIG. 19. If the modified gate 91 in an on-state, the MOSFET channel and SCR 24 underneath then dumps this charge into the base region 22.

The components shown in the figures follow, unless indicated otherwise, preferably in the specified sequence directly one on top of the other. Components which are not in contact in the figures are preferably spaced apart from one another. If lines are drawn parallel to one another, the corresponding surfaces are preferably oriented in parallel with one another. Likewise, unless indicated otherwise, the positions of the drawn components relative to one another are correctly reproduced in the figures.

The invention described here is not restricted by the description on the basis of the exemplary embodiments. Rather, the invention encompasses any new feature and also any combination of features, which includes in particular any combination of features in the patent claims, even if this feature or this combination itself is not explicitly specified in the patent claims or exemplary embodiments.

This patent application claims the priority of German patent application 10 2020 134 178.4, the disclosure content of which is hereby incorporated by reference.

### LIST OF REFERENCE SIGNS

1 photo sensor cell
2 semiconductor body
20 top side
21 well region
22 base region
23 well contact region
24 depletion region extended by the collection gate
25 depletion region
26 transfer depletion region
27 accumulation region
28 trap region
31 well electrode
32 base electrode
33 base connection line
4 collection gate electrode
41 gate extension of the collection gate electrode
42 central part of the collection gate electrode
43 collection gate insulator
5 transfer gate electrode
6 aperture
9 modified photo sensor cell
91 modified gate electrode
10 photo sensor
D scale parameter
e⁻ electron
E energy
h⁺ hole
P photon

1. A photo sensor cell comprising
a semiconductor body having a well region of a first conductivity type and at least one base region of a second conductivity type different from the first conductivity type,
a well electrode electrically contacting the well region and a base electrode electrically contacting the base region,
a collection gate electrode located on top of the well region next to the base region and, seen in top view of the collection gate electrode, at least partially surrounding the base region,
wherein the collection gate electrode comprises at least one gate extension running away from the base region and terminating within the semiconductor body, seen in top view of the collection gate electrode.

2. The photo sensor cell according to claim 1, wherein
when the collection gate electrode is in an off-state, there is a depletion region at an interface between the well region and the base region, the depletion region only partially burrows under the collection gate electrode,
when the collection gate electrode is in a collection-state, the depletion region is extended and/or completely burrows under the collection gate electrode, and
a maximum extent of the collection gate electrode exceeds a diameter of the base region by at least a factor of two, seen in top view of the collection gate electrode.

3. The photo sensor cell according to claim 1, wherein a maximum distance between any point of a top side of the semiconductor body and the nearest part of the collection gate electrode is at most 30 μm.

4. The photo sensor cell according to claim 1, wherein the collection gate electrode comprises at least two and at most eight of the gate extensions.

5. The photo sensor cell according to claim 1, wherein the at least one gate extension, or at least one of the gate extensions, is of T-shape or F-shape or double-F-shape so that a width of said collection gate electrode is largest at an end remote from the base region, seen in top view of the collection gate electrode.

6. The photo sensor cell according to claim 1, wherein the at least one gate extension, or at least one of the gate extensions, is of L-shape so that said collection gate electrode comprises exactly one kink and/or bend, seen in top view of the collection gate electrode.

7. The photo sensor cell according to claim 1, wherein the at least one gate extension, or at least one of the gate extensions, is of meander shape so that said collection gate electrode comprises a plurality of changes in direction, seen in top view of the collection gate electrode.

8. The photo sensor cell according to claim 1, comprising a plurality of the base regions and a plurality of the collection gate electrodes,
wherein at least two or each one of the base regions is assigned to one of the collection gate electrodes, and
wherein at least some of the base regions are electrically interconnected by at least one base connection line.

9. The photo sensor cell according to claim 1, further comprising a transfer gate electrode, wherein the transfer gate electrode is located between the base region and the collection gate electrode and is electrically independently addressable from the collection gate electrode, and wherein the transfer gate electrode is configured to form a transfer depletion region from below the collection gate electrode to the base region when in an on-state.

10. The photo sensor cell according to claim 1, wherein the transfer depletion region completely surrounds the base region, seen in top view of the collection gate electrode, and wherein the transfer depletion region and the collection gate electrode are disjunctive, seen in top view of the collection gate electrode.

11. The photo sensor cell according to claim 1, wherein the collection gate electrode comprises one or more than one axis of mirror symmetry, seen in top view of the collection gate electrode, and wherein the collection gate electrode surrounds the base region over an angle range of at least 330°, seen in top view of the collection gate electrode.

12. The photo sensor cell according to claim 1, comprising exactly the one well region, the one base region, the one base electrode and the one collection gate electrode, and wherein the base region is surrounded all around by the well region, seen in top view of the collection gate electrode.

13. The photo sensor cell according to claim 1, wherein the base region is n⁺-doped and the well region is p-doped, and wherein the semiconductor body is of silicon and further comprises a base contact region which is p⁺-doped and which is electrically between the well electrode and the well region.

14. A photo sensor comprising a plurality of the photo sensor cells according to claim 1, wherein the photo sensor cells are arranged adjacent to one another, seen in top view of the collection gate electrodes.

15. A method of operating a photo sensor cell according to claim 1, comprising
illuminating the photo sensor cell with electromagnetic radiation so that electron-hole pairs are generated in the semiconductor body, and
providing a gate voltage to the collection gate electrode, so that a collection region for charge carriers in the semiconductor body towards the base region is increased compared with an off-state of the collection gate electrode.
